(19) United States
(12) Patent Application Publication
(10) Pub. No.: US 2011/0065030 A1
(43) Pub. Date: Mar. 17, 2011

(54) MASK PATTERN DETERMINING METHOD, MASK MANUFACTURING METHOD, AND DEVICE MANUFACTURING METHOD

(76) Inventors: Toshiya KOTANI, Tokyo (JP); Fumiharu Nakajima, Kanagawa (JP); Ryota Aburada, Kanagawa (JP); Takafumi Taguchi, Kanagawa (JP); Hiromitsu Mashita, Kanagawa (JP); Michiya Takimoto, Kanagawa (JP); Chikaaki Kodama, Kanagawa (JP)

(21) Appl. No.: 12/880,507

(22) Filed: Sep. 13, 2010

(30) Foreign Application Priority Data
Sep. 17, 2009 (JP) 2009-216106

(51) Int. Cl. G03F 7/20; G06F 17/50

(52) U.S. Cl. 430/30; 716/51

(57) ABSTRACT

According to one embodiment, a mask pattern determining method includes a mask-pattern dimension variation amount of a first photomask is derived. Moreover, a correspondence relationship between a target dimension value of an on-substrate test pattern formed by using a second photomask and a dimension allowable variation amount of a mask pattern formed on the second photomask is derived. Then, it is determined whether pattern formation is possible with a pattern dimension that needs to be formed when performing the pattern formation on a substrate by using the first photomask based on the mask-pattern dimension variation amount and the correspondence relationship.

### CROSS-REFERENCE TO RELATED APPLICATIONS

This application is based upon and claims the benefit of priority from the prior Japanese Patent Application No. 2009-216106, filed on Sep. 17, 2009; the entire contents of which are incorporated herein by reference.

### FIELD

Embodiments described herein relate generally to a mask pattern determining method, a mask manufacturing method, and a device manufacturing method.

### BACKGROUND

The recent progress of a semiconductor manufacturing technology is extremely remarkable, and semiconductor devices (semiconductor integrated circuits) with a minimum feature size of 50 nm are mass-produced. Micropatterning of patterns constituting the semiconductor device is realized by breakthrough in a lithography technology. With such micropatterning, it is strongly demanded to improve a dimension accuracy of a photomask used when performing a pattern transfer. Therefore, variation in a pattern dimension of the photomask to be exposed when forming a micropattern needs to be managed with extremely strict specification.

For example, there is a pattern forming method of correcting a comprehensive dimension variation that occurs comprehensively at the time of manufacturing a mask and manufacturing a high-accuracy mask. However, after manufacturing the mask, a target dimension value of the micropattern formed on a substrate is slightly changed from an assumed value in some cases in view of balance with a process margin other than the lithography at the time of product mass-production to the substrate. For example, the mask in which the micropattern dimension assumed at the time of manufacturing the mask can be formed cannot ensure sufficient lithography margin in some cases due to change of the target dimension value to be formed on the substrate. Therefore, there is a problem in that even if a pattern with the target dimension value different from a pattern dimension assumed value at the time of manufacturing the mask is to be formed on the substrate, the pattern cannot be formed on the substrate with a pattern dimension as the target dimension value. Thus, if it is failed to determine the pattern dimension that can be formed on the substrate by using the mask, a dimensional error of a pattern occurs in some cases when the pattern is formed on the substrate.

### BRIEF DESCRIPTION OF THE DRAWINGS

FIG. 1 is a block diagram illustrating a configuration of a mask determining apparatus according to a present embodiment;

FIG. 2 is a flowchart illustrating a process procedure of a mask determining process according to the present embodiment;

FIG. 3 is a diagram illustrating an example of a mask dimension variation curve;

FIG. 4 is a diagram for explaining a product-mask variation amount;

FIG. 5A and FIG. 5B are diagrams for explaining a usable dimension range;

FIG. 6 is a diagram illustrating an example of the mask dimension variation curve when there are two elements of the on-mask allowable dimension variation amount;

FIG. 7 is a diagram for explaining an example of the usable dimension range derived by using FIG. 6; and

FIG. 8 is a diagram illustrating a hardware configuration of the pattern determining apparatus.

### DETAILED DESCRIPTION

In general, according to one embodiment, a mask pattern determining method includes a dimension variation amount of a mask pattern formed on a first photomask that is a determination target of a mask pattern dimension is derived as dimension variation amount information.

A dimension range of an on-substrate pattern formable with a desired dimension on a substrate by using the first photomask is then derived as a usable dimension range based on correspondence relationship information that is a correspondence relationship between a target dimension value of an on-substrate test pattern formed on the substrate by using a second photomask for test and an allowable variation amount of a dimension of a mask pattern formed on the second photomask and the dimension variation amount information.

After that, the usable dimension range is compared with a pattern dimension of the on-substrate pattern that needs to be formed by using the first photomask to determine whether it is possible to form the on-substrate pattern with a pattern dimension that needs to be formed upon forming the on-substrate pattern by using the first photomask.

A mask pattern determining method, a mask manufacturing method, and a device manufacturing method according to the embodiments will be explained below in detail with reference to the accompanying drawings. The present invention is not limited to the embodiments.

### Embodiment

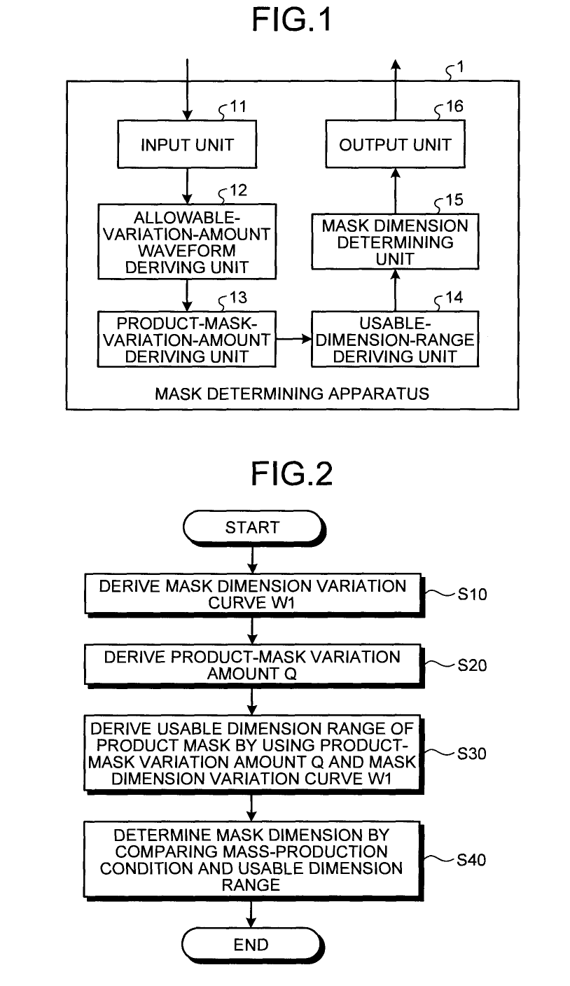

FIG. 1 is a block diagram illustrating a configuration of a mask determining apparatus according to a present embodiment. A mask determining apparatus 1 is an apparatus, such as a computer, that determines whether a dimension of a mask pattern formed on a photomask is an appropriate dimension for forming a resist pattern having a desired shape. The mask determining apparatus 1 in the present embodiment performs a dimension assurance of the mask pattern by determining acceptance or rejection of the dimension of the mask pattern.

The mask determining apparatus 1 includes an input unit 11, an allowable-variation-amount waveform deriving unit 12, a product-mask-variation-amount deriving unit 13, a usable-dimension-range deriving unit 14, a mask dimension determining unit 15, and an output unit 16.

The input unit 11 inputs various information used in determination of the mask dimension from an external device or the like. An assumed value (dimension predetermined value at the time of manufacturing a mask) of a dimension of a pattern (for example, resist pattern) (hereinafter, on-wafer pattern) to be formed on a substrate such as a wafer, mask pattern data for forming the on-wafer pattern of the assumed value, an exposure condition for forming the on-wafer pattern, and the like are input to the input unit 11. One to a plurality of the assumed values of the on-wafer pattern is input to the input unit 11. For example, when the on-wafer patterns of 43 nm and 50 nm are supposed to be formed, 43 nm and 50 nm are input as the assumed values. The mask pattern data input to the input unit 11 is a test pattern (test mask pattern) for deriving a mask dimension variation curve to be described later and is data on the mask pattern with which the on-wafer pattern of the assumed value can be formed.

Moreover, the mask pattern data on a product mask pattern formed on the photomask (product mask) that is supposed to be used for manufacturing a semiconductor device is input to the input unit 11.

The allowable-variation-amount waveform deriving unit 12 derives an allowable dimension variation amount (hereinafter, on-wafer allowable dimension variation amount W) when the on-wafer pattern is formed with various target dimension values (dimension values obtained by adding various shift amounts to the assumed value) by using the assumed value, the mask pattern data on the test mask, and the exposure condition input to the input unit 11. The on-wafer allowable dimension variation amount W is a shift amount (for example, 2 nm) of the dimension value of the on-wafer pattern that is allowed when forming the on-wafer pattern with the target dimension value.

The allowable-variation-amount waveform deriving unit 12 in the present embodiment sets a predetermined lithography margin so that a desired yield can be ensured. The allowable-variation-amount waveform deriving unit 12 derives the dimension value of the on-wafer pattern when forming a pattern on a wafer by the mask pattern of the test mask by using the exposure condition, by a lithography simulation or the like for each assumed value. The allowable-variation-amount waveform deriving unit 12 derives the on-wafer allowable dimension variation amount W based on the derived dimension value of the on-wafer pattern and the shift amount of the dimension value of the on-wafer pattern with which a desired yield can be ensured. The allowable-variation-amount waveform deriving unit 12 derives the on-wafer allowable dimension variation amount W for each target dimension value.

The allowable-variation-amount waveform deriving unit 12 derives an allowable dimension variation amount (hereinafter, on-mask allowable dimension variation amount P) on a mask of the mask pattern used for forming the on-wafer pattern for each target dimension value by using the derived on-wafer allowable dimension variation amount W. In other words, the allowable-variation-amount waveform deriving unit 12 converts the on-wafer allowable dimension variation amount W into the on-mask allowable dimension variation amount P for each target dimension value. The allowable-variation-amount waveform deriving unit 12 derives the on-mask allowable dimension variation amount P by the lithography simulation or the like using the on-wafer allowable dimension variation amount W. The allowable-variation-amount waveform deriving unit 12 derives a correspondence relationship (mask dimension variation curves W1 and W2 to be described later) between the target dimension value and the on-mask allowable dimension variation amount P by using the on-mask allowable dimension variation amount P.

The product-mask-variation-amount deriving unit 13 derives a pattern dimension variation amount on the product mask by using the mask pattern data on the product mask, the exposure condition, and the like. The product-mask-variation-amount deriving unit 13 derives the pattern dimension variation amount of the product mask, for example, by the lithography simulation.

The usable-dimension-range deriving unit 14 derives a dimension range of the on-wafer pattern that is allowed to be formed on a wafer by using the product mask (dimension can be assured) based on the mask dimension variation curves W1 and W2 derived by the allowable-variation-amount waveform deriving unit 12 and the on-mask dimension variation amount of the product mask derived by the product-mask-variation-amount deriving unit 13. The dimension range of the on-wafer pattern that is allowed to be formed on a wafer by using the product mask is a dimension range (hereinafter, usable dimension range) that is allowed to be set as the target dimension value (mass-production condition) at the mass-production. In the present embodiment, the usable dimension range is derived, which can ensure a predetermined lithography margin even if the resist target dimension on a wafer varies.

The mask dimension determining unit 15 determines acceptance or rejection of the mask pattern dimension of the product mask by comparing the usable dimension range derived by the usable-dimension-range deriving unit 14 with the actual mass-production condition (target dimension value of the wafer pattern at the mass-production). If the actual mass-production condition is within the usable dimension range, the mask dimension determining unit 15 determines to accept the product mask, and if the actual mass-production condition is out of the usable dimension range, the mask dimension determining unit 15 determines to reject the product mask. In other words, if the actual mass-production condition is within the usable dimension range, the mask dimension determining unit 15 determines to accept the mass-production condition, and if the actual mass-production condition is out of the usable dimension range, the mask dimension determining unit 15 determines to reject the mass-production condition. The output unit 16 outputs the determination result by the mask dimension determining unit 15.

Next, a process procedure of a mask determining process (mask dimension assurance process) is explained. FIG. 2 is a flowchart illustrating the process procedure of the mask determining process according to the present embodiment. The assumed value (for example, 43 nm) of the on-wafer pattern, the mask pattern data on the test mask, the exposure condition for forming the on-wafer pattern, the mask pattern data on the product mask pattern, and the like are input to the input unit 11 of the mask determining apparatus 1.

The allowable-variation-amount waveform deriving unit 12 derives the on-wafer allowable dimension variation amount W when forming the on-wafer pattern with various target dimension values by using the assumed value, the mask pattern data on the test mask, and the exposure condition input to the input unit 11.

Moreover, the allowable-variation-amount waveform deriving unit 12 derives the on-mask allowable dimension variation amount P when forming the on-wafer pattern of the target dimension value by using the derived on-wafer allowable dimension variation amount W. The allowable-variation-amount waveform deriving unit 12 derives the on-mask allowable dimension variation amount P for various target dimension values (for example 30 nm to 55 nm). Whereby, the allowable-variation-amount waveform deriving unit 12 derives a correspondence relationship between the target dimension value and the on-mask allowable dimension variation amount P as the mask dimension variation curve W1 (Step S10). In this manner, in the present embodiment, a plurality of the target dimension values is set and the on-mask allowable dimension variation amount P is derived for each target dimension value, thereby deriving the mask dimension variation curve W1 in advance.

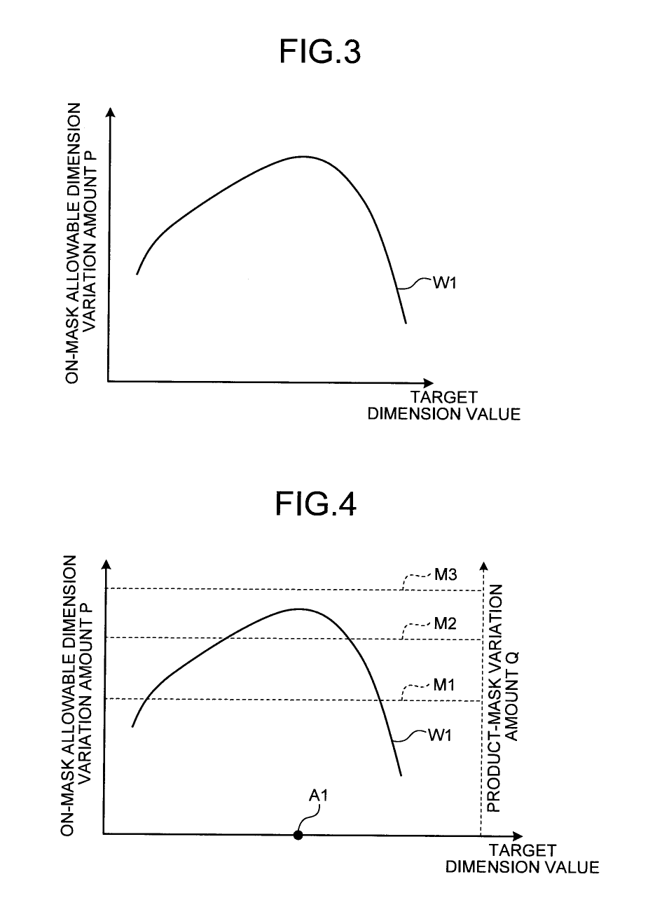

FIG. 3 is a diagram illustrating an example of the mask dimension variation curve. FIG. 3 illustrates the mask dimension variation curve W1 of the product pattern whose assumed value is 43 nm. In a graph in FIG. 3, a horizontal axis indicates the target dimension value and a vertical axis indicates the on-mask allowable dimension variation amount P. In the mask dimension variation curve W1, the value of the on-mask allowable dimension variation amount P changes in accordance with the target dimension value. If a dimension variation amount (hereinafter, product-mask variation amount Q) of the product mask to be derived thereafter is on the lower side of the on-mask allowable dimension variation amount P indicated by the mask dimension variation curve W1, the mask pattern dimension of the product mask is determined to be accepted.

The product-mask-variation-amount deriving unit 13 derives the product-mask variation amount Q by using the mask pattern of the product mask, the exposure condition, and the like (Step S20). The usable-dimension-range deriving unit 14 derives the usable dimension range by using the mask dimension variation curve W1 derived by the allowable-variation-amount waveform deriving unit 12 and the product-mask variation amount Q derived by the product-mask-variation-amount deriving unit 13 (Step S30).

FIG. 4 is a diagram for explaining the product-mask variation amount. In this example, explanation is given for the case where the manufactured product mask (determination target) is a first mask, a second mask, and a third mask. FIG. 4 illustrates the product-mask variation amount Q of the first mask, the second mask, and the third mask on the graph (the mask dimension variation curve W1) shown in FIG. 3 as product-mask dimension variation amounts M1 to M3.

FIG. 4 illustrates the case where the assumed value (target dimension value that is first assumed for a mask) is a dimension A1. In the case of the third mask having the product-mask dimension variation amount M3, even if the pattern formation is performed on a wafer with any target dimension value, the product-mask variation amount Q that is larger than the value of the on-mask allowable dimension variation amount P indicated by the mask dimension variation curve W1 occurs. On the other hand, in the case of the first mask having the product-mask dimension variation amount M1 or the second mask having the product-mask dimension variation amount M2, if the pattern formation is performed on a wafer with a predetermined target dimension value, the pattern formation can be performed with the product-mask variation amount Q that is smaller than the value of the on-mask allowable dimension variation amount P indicated by the mask dimension variation curve W1.

In the present embodiment, the target dimension value for the pattern formation on a wafer is determined for each product mask, with which the pattern formation can be performed with the product-mask variation amount Q that is smaller than the value of the on-mask allowable dimension variation amount P indicated by the mask dimension variation curve W1.

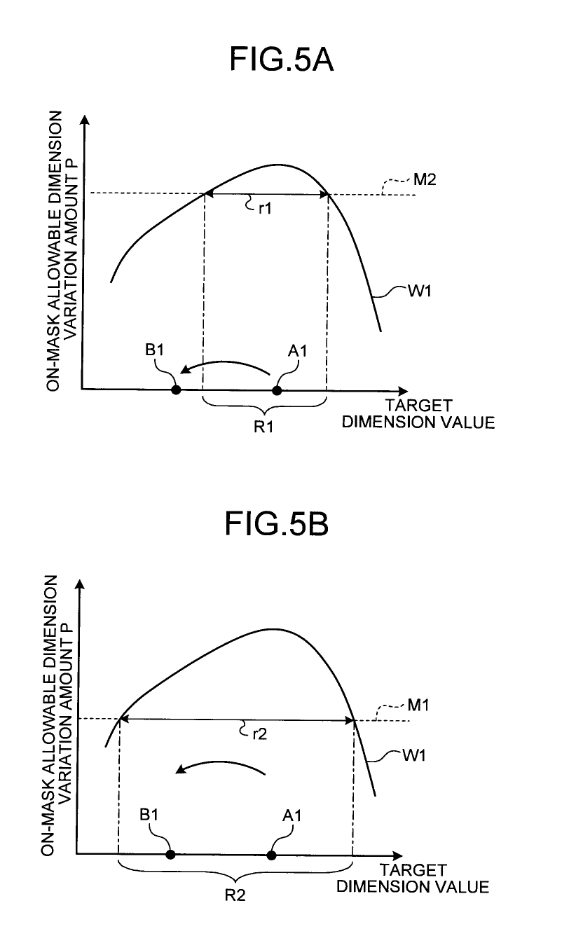

FIG. 5A and FIG. 5B are diagrams for explaining the usable dimension range. FIG. 5A illustrates a usable dimension range R1 of the second mask and FIG. 5B illustrates a usable dimension range R2 of the first mask.

As shown in FIG. 5A, the range of the target dimension value corresponding to a range r1 sandwiched between intersections of the mask dimension variation curve W1 and the product-mask dimension variation amount M2 of the second mask becomes the usable dimension range R1 of the second mask.

As shown in FIG. 5B, the range of the target dimension value corresponding to a range r2 sandwiched between intersections of the mask dimension variation curve W1 and the product-mask dimension variation amount M1 of the first mask becomes the usable dimension range R2 of the first mask.

The usable-dimension-range deriving unit 14 derives the usable dimension range R2 of the first mask by using the mask dimension variation curve W1 and the product-mask dimension variation amount M1 of the first mask, and derives the usable dimension range R1 of the second mask by using the mask dimension variation curve W1 and the product-mask dimension variation amount M2 of the second mask.

The mask dimension determining unit 15 determines the dimension of the mask pattern of the product mask by comparing the usable dimension range R1 or the usable dimension range R2 derived by the usable-dimension-range deriving unit 14 with the actual mass-production condition (Step S40). For example, FIG. 5A or FIG. 5B illustrates the case where the assumed value is the dimension A1 and the mass-production condition (target dimension value changed at the mass-production) is a dimension B1. When the pattern dimension on a wafer to be formed by using the product mask is changed from the dimension A1 of the assumed value to the dimension B1 of the mass-production condition, the dimension B1 of the mass-production condition may fall outside of the usable dimension range. In the present embodiment, when the pattern dimension on a wafer to be formed by using the product mask is changed from the dimension A1 of the assumed value to the dimension B1 of the mass-production condition, the mask dimension determining unit 15 determines whether the product mask can be used in the mass-production condition based on whether the dimension B1 of the mass-production condition is within the range of the usable dimension range.

If the mass-production condition is within the usable dimension range, the mask dimension determining unit 15 determines to accept the product mask, and if the mass-production condition is out of the usable dimension range, the mask dimension determining unit 15 determines to reject the product mask. For example, in the case of the product-mask dimension variation amount M2 of the second mask shown in FIG. 5A, when the pattern dimension on a wafer to be formed is changed from the dimension A1 of the assumed value to the dimension B1 of the mass-production condition, the dimension B1 falls outside of the usable dimension range R1. Therefore, the mask dimension determining unit 15 determines that the second mask cannot be used for the mass-production with the dimension B1. In other words, the second mask has no problem when used for the pattern formation with the assumed value, however cannot be used for the pattern formation in the mass-production condition.

On the other hand, in the case of the product-mask dimension variation amount M1 of the first mask shown in FIG. 5B, even if the pattern dimension on a wafer to be formed is changed from the dimension A1 of the assumed value to the dimension B1 of the mass-production condition, the dimension B1 falls within the usable dimension range R2. Therefore, the mask dimension determining unit 15 determines that the first mask can be used for the mass-production with the dimension B1. In other words, for the product mask with relatively small product-mask dimension variation amount such as the first mask, both of the assumed value and the mass-production condition fall inside (lower side) of the mask dimension variation curve W1, so that it is possible to determine that the production mask can be used with no problem even in the mass-production condition. The output unit 16 outputs the determination result by the mask dimension determining unit 15.

The target dimension value on the horizontal axis shown in FIG. 3 to FIG. 5B corresponds to exposure dose (appropriate exposure dose) used when forming the on-wafer pattern. Therefore, the usable dimension range corresponds to the range of the appropriate exposure dose.

In this manner, because the usable dimension range is derived by using the mask dimension variation curve W1 and the dimension variation amount of the product mask (such as the first to third masks), it becomes possible to correctly derive the range of the target dimension value applicable to the product mask, so that a use condition of each product mask is clarified. Therefore, it becomes possible to define the range (usable dimension range) of the target dimension value at the mass-production of products that is applicable for the product mask or the appropriate exposure dose range for each product mask. Consequently, it becomes possible to determine whether each product mask is applicable with respect to the target dimension value in the mass-production condition, so that it is possible to determine whether the product mask is applicable to the mass-production condition without performing a yield evaluation. Thus, a load on determination of acceptance or rejection of the product mask by a product verification can be reduced, so that faster mass-production application determination can be realized.

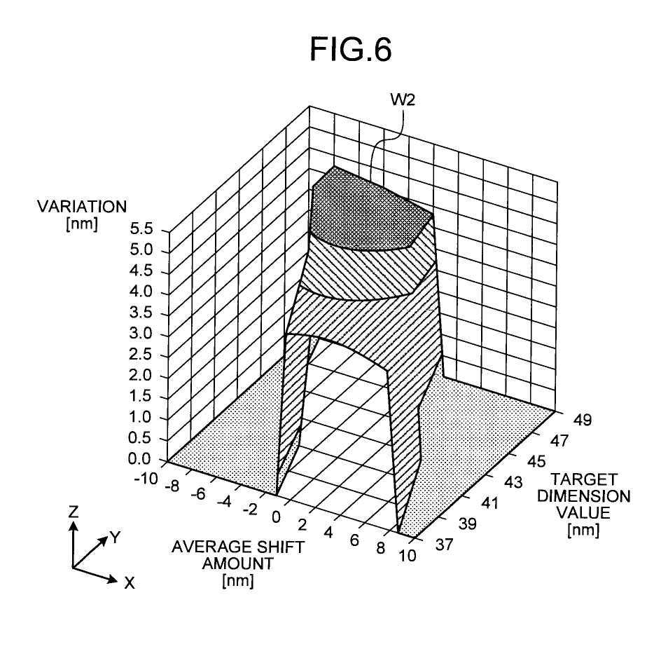

Next, explanation is given for the case where the on-mask allowable dimension variation amount P has two elements, i.e., a mask in-plane variation and a mask in-plane average-value shift (average-value shift amount). FIG. 6 is a diagram illustrating an example of the mask dimension variation curve when there are two elements of the on-mask allowable dimension variation amount P. The graph in FIG. 6 three-dimensionally illustrates a correspondence relationship between the target dimension value and the on-mask allowable dimension variation amount P. The on-mask allowable dimension variation amount P in this example is separated into two, i.e., the mask in-plane variation (for example, 3σ) of the mask pattern dimension (litho target dimension) and a shift amount (average-value shift amount) of the litho target dimension from the average value. In the graph in FIG. 6, an X axis indicates the average-value shift amount, a Y axis indicates the target dimension value, and a Z axis indicates a variation (mask in-plane variation).

The mask dimension variation curve W2 is derived by the allowable-variation-amount waveform deriving unit 12 by using the lithography simulation or the like. The mask dimension can be defined on a space by using the mask dimension variation curve W2. It is possible to determine the range of the target dimension value in which the product mask can be used by projecting a plan view obtained by cutting the mask dimension variation curve W2 at a mask dimension surface corresponding to the product mask on an axis side of the target dimension value.

For example, when the mask dimension surface corresponding to the product mask is the average-value shift amount, the curve (correspondence relationship between variation and target dimension value) like the mask dimension variation curve W1 shown in FIG. 3 can be obtained by projecting the plan view (curve on a YZ plane) obtained by cutting the mask dimension variation curve W2 at the YZ plane (for example, X=2) on the YZ plane present on the axis of the target dimension value. The range of the target dimension value corresponding to the range sandwiched between intersections of the curve (mask dimension variation curve W3 to be described later) when projecting the plan view obtained by cutting the mask dimension variation curve W2 on the axis side of the target dimension value and the product-mask variation amount Q is the usable dimension range of the product mask.

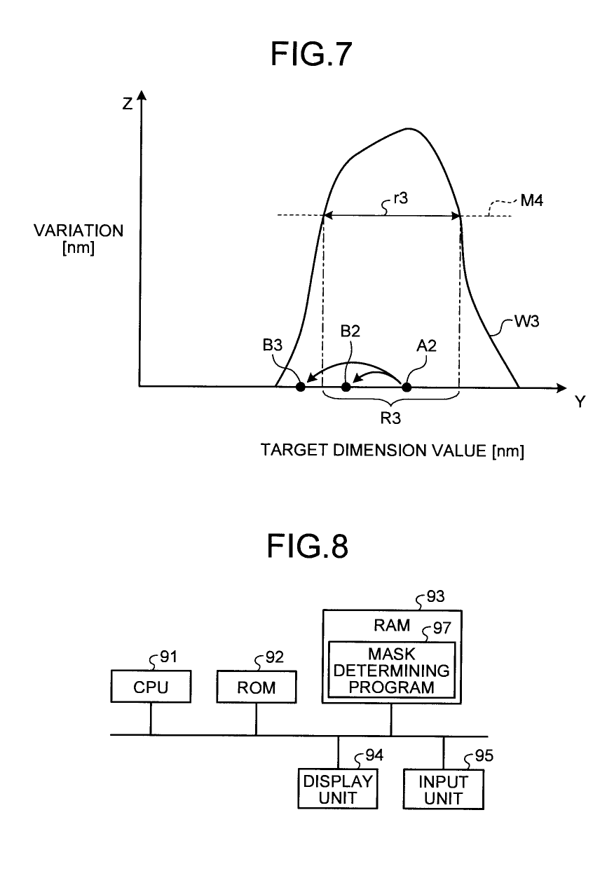

FIG. 7 is a diagram for explaining an example of the usable dimension range derived by using FIG. 6. FIG. 7 illustrates the mask dimension variation curve W3 when projecting the plan view obtained by cutting the graph (the mask dimension variation curve W2) shown in FIG. 6 by the YZ plane on the YZ plane present on the axis of the target dimension value and a product-mask dimension variation amount M4 of a fourth mask.

As shown in FIG. 7, the range of the target dimension value corresponding to a range r3 sandwiched between the intersections of the mask dimension variation curve W3 and the product-mask dimension variation amount M4 of the fourth mask becomes a usable dimension range R3 of the fourth mask.

The usable dimension range R3 shown in FIG. 7 is derived by the usable-dimension-range deriving unit 14. The mask dimension determining unit 15 determines the dimension of the mask pattern of the product mask by comparing the usable dimension range R3 derived by the usable-dimension-range deriving unit 14 with the actual mass-production condition. For example, FIG. 7 illustrates the case where the assumed value is the dimension A2 and the mass-production condition is the dimension B2 or the dimension B3.

For example, in the case of the product-mask dimension variation amount M4 of the fourth mask shown in FIG. 7, when the pattern dimension on a wafer to be formed is changed from the dimension A2 of the assumed value to the dimension B3 of the mass-production condition, the dimension B3 falls outside of the usable dimension range R3. Therefore, the mask dimension determining unit 15 determines rejection of the application of the fourth mask to the dimension B3 of the mass-production condition. In other words, the fourth mask has no problem when used for the pattern formation in which the assumed value is the dimension A2, however cannot be used for the pattern formation with the dimension B3 of the mass-production condition.

On the other hand, even if the pattern dimension on a wafer to be formed is changed from the dimension A2 of the assumed value to the dimension B2 of the mass-production condition, the dimension B2 falls within the usable dimension range R3. Therefore, the mask dimension determining unit 15 determines acceptance of the application of the fourth mask to the dimension B2 of the mass-production condition.

The product mask (product mask that is determined so that it can be used for the target dimension value in the mass-production condition) whose pattern dimension is determined to be accepted by the mask determining apparatus 1 is used in a wafer process to manufacture a semiconductor device (semiconductor integrated circuit). Specifically, an exposure apparatus performs an exposure process on a wafer by using the product mask determined to be accepted, and thereafter, a development process and an etching process on the wafer are performed. In other words, a mask material is processed with a resist pattern formed by transfer in the lithography process and further a process target film is etched to be patterned by using the patterned mask material. When manufacturing a semiconductor device, the above exposure process, development process, and etching process are repeated for each layer.

Determination of the pattern dimension of the product mask is performed, for example, for each layer (each product mask) of the wafer process. Then, the exposure process of the wafer for each layer is performed by using the product mask determined to be accepted to manufacture a semiconductor device.

When the pattern dimension is determined to be rejected by the mask determining apparatus 1, at least one of the pattern dimension in the mass-production condition, the dimension allowable variation range on a wafer, the product mask, photomask data for generating the product mask, and the exposure condition (hereinafter, change elements) is changed so that the pattern dimension is accepted. For example, the allowable-variation-amount waveform deriving unit 12 derives the mask dimension variation curves W1 to W3 as functions. Then, the change element is changed so that the mass-production condition falls within the usable dimension range based on the functions of the mask dimension variation curves W1 to W3. In other words, the change element is changed by a change amount for the mass-production condition to fall within the usable dimension range.

Next, explanation is given for a difference between a conventional mask pattern determining method and the mask pattern determining method in the present embodiment. In the conventional mask pattern determining method, a pattern to be determined on the photomask is selected and the target dimension value of an on-substrate pattern to be formed on the substrate by using this pattern is derived. The dimension allowable variation amount of the on-substrate pattern due to the photomask dimension variation is derived for this target dimension value in view of design, process, and device operation. Moreover, the dimension allowable variation amount of the photomask pattern that causes this dimension allowable variation amount is derived. Then, if the dimension of the manufactured photomask falls within the derived dimension allowable variation amount of the photomask pattern, the photomask is determined to be accepted, and if the dimension does not fall within the derived dimension allowable variation amount, the photomask is determined to be rejected. Therefore, when the photomask determined to be accepted is exposed with the assumed target dimension value, the dimension variation falls within the range of the dimension allowable variation amount on the substrate, so that there is no problem to apply to the photomask at the time of manufacture of products.

However, there is a case where the assumed target dimension value is slightly changed due to a process margin balance with a process (for example, etching process and embedding process) other than the lithography. In this case, exposure is performed so that the on-wafer pattern dimension becomes different from the assumed target dimension value, therefore it becomes difficult to ensure that the dimension variation falls within the range of a predetermined dimension allowable variation amount. Typically, such a change of the target dimension value is often realized by a method such as changing exposure dose of the exposure apparatus, changing a focus, and changing an illumination condition. In this manner, when a process or the like is changed from the assumed condition, a product verification in a through process is performed, presence or absence of a problem is determined, and a process change is approved when it is determined that there is no problem. The problem in this case is that because the dimension allowable variation amount of the photomask is set based on the target dimension value that is first assumed, discrepancy occurs in the dimension allowable variation amount of the photomask.

On the other hand, in the mask pattern determining method in the present embodiment, the usable dimension range is derived by using the mask dimension variation curves W1 and W2 and the dimension variation amount of the product mask, so that the mask determination of the product mask can be performed easily and correctly by comparing the usable dimension range with the mass-production condition.

FIG. 8 is a diagram illustrating a hardware configuration of the pattern determining apparatus. The mask determining apparatus 1 includes a CPU (Central Processing Unit) 91, a ROM (Read Only Memory) 92, a RAM (Random Access Memory) 93, a display unit 94, and an input unit 95. In the mask determining apparatus 1, the CPU 91, the ROM 92, the RAM 93, the display unit 94, and the input unit 95 are connected via a bus line.

The CPU 91 executes the dimension determination of a mask pattern by using a mask determining program 97 that is a computer program. The display unit 94 is a display device such as a liquid crystal monitor, and displays the mask pattern, the on-wafer allowable dimension variation amount W, the on-mask allowable dimension variation amount P, the mask dimension variation curves W1 and W2, the product-mask variation amount Q, the usable dimension range, and the like based on an instruction from the CPU 91. The input unit 95 is configured to include a mouse and a keyboard, and inputs instruction information (such as parameter necessary for dimension determination of the mask pattern) that is externally input by a user. The instruction information input to the input unit 95 is sent to the CPU 91.

The mask determining program 97 is stored in the ROM 92 and is loaded in the RAM 93 via the bus line. The CPU 91 executes the mask determining program 97 loaded in the RAM 93. Specifically, in the mask determining apparatus 1, the CPU 91 reads out the mask determining program 97 from the ROM 92, loads it in a program storage area in the RAM 93, and executes various processes, in accordance with the input of an instruction by a user from the input unit 95. The CPU 91 temporarily stores various data generated in the various processes in the data storage area formed in the RAM 93.

The mask determining program 97 executed in the mask determining apparatus 1 has a module configuration including the above respective units (the allowable-variation-amount waveform deriving unit 12, the product-mask-variation-amount deriving unit 13, the usable-dimension-range deriving unit 14, the mask dimension determining unit 15, and the output unit 16), which are loaded in a main storage device, whereby the input unit 11, the allowable-variation-amount waveform deriving unit 12, the product-mask-variation-amount deriving unit 13, the usable-dimension-range deriving unit 14, the mask dimension determining unit 15, and the output unit 16 are generated on the main storage device.

In the present embodiment, the pattern dimension of the product mask is determined; however, the photomask for determining the pattern dimension is not limited to the product mask and any photomask (such as photomask for experiment) can be used.

Moreover, in the present embodiment, the case is explained in which the mask dimension variation curves W1 and W2 are derived by the lithography simulation; however, the mask dimension variation curves W1 and W2 can be determined by experiment. In this case, it is applicable that the mask determining apparatus 1 does not include the allowable-variation-amount waveform deriving unit 12. When the mask dimension variation curves W1 and W2 are determined by experiment, various pattern dimensions are formed on a wafer under various exposure conditions, and the on-wafer allowable dimension variation amount W of the formed on-wafer patterns is measured. Then, the on-mask allowable dimension variation amount P is derived by using the on-wafer allowable dimension variation amount W, and the mask dimension variation curves W1 and W2 are generated by associating the derived on-mask allowable dimension variation amount P with the target dimension value.

Furthermore, in the present embodiment, the case is explained in which the product-mask variation amount Q is derived after deriving the mask dimension variation curve W1 or the mask dimension variation curve W2; however, the mask dimension variation curve W1 or the mask dimension variation curve W2 can be derived after deriving the product-mask variation amount Q.

In this manner, according to the present embodiment, the usable dimension range is derived based on the mask dimension variation curves W1 and W2 and the product-mask variation amount Q, so that quality of the product mask can be correctly defined. Moreover, the dimension determination of the mask pattern is performed by comparing the usable dimension range with the mass-production condition, so that it is possible to correctly perform the dimension determination of the mask pattern formed on the photomask and shorten the time required for verification of the product mask. Thus, the dimension assurance of the mask pattern formed on the photomask can be performed correctly in a short time.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of determining a mask pattern, comprising:
deriving a dimension variation amount of a mask pattern formed on a first photomask that is a determination target of a mask pattern dimension as dimension variation amount information;
deriving a dimension range of an on-substrate pattern formable with a desired dimension on a substrate by using the first photomask as a usable dimension range based on correspondence relationship information that is a correspondence relationship between a target dimension value of an on-substrate test pattern formed on a substrate by using a second photomask for test and an allowable variation amount of a dimension of a mask pattern formed on the second photomask and the dimension variation amount information; and
determining whether it is possible to form the on-substrate pattern with a pattern dimension that needs to be formed when forming the on-substrate pattern by using the first photomask by comparing the usable dimension range and a pattern dimension of the on-substrate pattern that needs to be formed by using the first photomask.

2. The method according to claim 1, wherein the usable dimension range is a range of the target dimension value corresponding to a range that is smaller than the allowable variation amount and is larger than the dimension variation amount information.

3. The method according to claim 1, further comprising:
determining that it is possible to form the on-substrate pattern with the pattern dimension that needs to be formed by using the first photomask if the pattern dimension that needs to be formed is within the usable dimension range; and
determining that it is not possible to form the on-substrate pattern with the pattern dimension that needs to be formed even by using the first photomask if the pattern dimension that needs to be formed is out of the usable dimension range.

4. The method according to claim 1, wherein the dimension variation amount information includes at least one of a shift amount from a dimension average value of the mask pattern and an in-plane variation of the mask pattern.

5. The method according to claim 1, further comprising deriving the dimension variation amount information by using mask pattern data on the first photomask and an exposure condition when forming the on-substrate pattern.

6. The method according to claim 1, further comprising deriving the allowable variation amount by using a dimension predetermined value of the on-substrate test pattern set when manufacturing the second photomask, mask pattern data on the second photomask, and an exposure condition when forming the on-substrate test pattern.

7. The method according to claim 1, further comprising deriving the allowable variation amount by a lithography simulation.

8. A method of manufacturing a mask, comprising:
deriving a dimension variation amount of a mask pattern formed on a first photomask that is a determination target of a mask pattern dimension as dimension variation amount information;
deriving a dimension range of an on-substrate pattern formable with a desired dimension on a substrate by using the first photomask as a usable dimension range based on correspondence relationship information that is a correspondence relationship between a target dimension value of an on-substrate test pattern formed on a substrate by using a second photomask for test and an allowable variation amount of a dimension of a mask pattern formed on the second photomask and the dimension variation amount information; and
correlating the first photomask with the usable dimension range.

9. The method according to claim 8, further comprising determining whether it is possible to form the on-substrate pattern with a pattern dimension that needs to be formed when forming the on-substrate pattern by using the first photomask by comparing the usable dimension range and a pattern dimension of the on-substrate pattern that needs to be formed by using the first photomask.

10. The method according to claim 8, wherein the usable dimension range is a range of the target dimension value corresponding to a range that is smaller than the allowable variation amount and is larger than the dimension variation amount information.

11. The method according to claim 8, further comprising:
determining that it is possible to form the on-substrate pattern with the pattern dimension that needs to be formed by using the first photomask if the pattern dimension that needs to be formed is within the usable dimension range; and
determining that it is not possible to form the on-substrate pattern with the pattern dimension that needs to be formed even by using the first photomask if the pattern dimension that needs to be formed is out of the usable dimension range.

12. The method according to claim 8, wherein the dimension variation amount information includes at least one of a shift amount from a dimension average value of the mask pattern and an in-plane variation of the mask pattern.

13. The method according to claim 8, further comprising deriving the dimension variation amount information by using mask pattern data on the first photomask and an exposure condition when forming the on-substrate pattern.

14. The method according to claim 8, further comprising deriving the allowable variation amount by using a dimension predetermined value of the on-substrate test pattern set when manufacturing the second photomask, mask pattern data on the second photomask, and an exposure condition when forming the on-substrate test pattern.

15. The method according to claim 8, further comprising deriving the allowable variation amount by a lithography simulation.

16. A method of manufacturing a device, comprising
deriving a dimension variation amount of a mask pattern formed on a first photomask that is a determination target of a mask pattern dimension as dimension variation amount information;
deriving a dimension range of an on-substrate pattern formable with a desired dimension on a substrate by using the first photomask as a usable dimension range based on correspondence relationship information that is a correspondence relationship between a target dimension value of an on-substrate test pattern formed on a substrate by using a second photomask for test and an allowable variation amount of a dimension of a mask pattern formed on the second photomask and the dimension variation amount information;
determining whether it is possible to form the on-substrate pattern with a pattern dimension that needs to be formed when forming the on-substrate pattern by using the first photomask by comparing the usable dimension range and a pattern dimension of the on-substrate pattern that needs to be formed by using the first photomask; and
forming the on-substrate pattern by using the first photomask that is determined to be capable of forming the on-substrate pattern with the pattern dimension that needs to be formed.

17. The method according to claim 16, wherein the usable dimension range is a range of the target dimension value corresponding to a range that is smaller than the allowable variation amount and is larger than the dimension variation amount information.

18. The method according to claim 16, further comprising:
determining that it is possible to form the on-substrate pattern with the pattern dimension that needs to be formed by using the first photomask if the pattern dimension that needs to be formed is within the usable dimension range; and
determining that it is not possible to form the on-substrate pattern with the pattern dimension that needs to be formed even by using the first photomask if the pattern dimension that needs to be formed is out of the usable dimension range.

19. The method according to claim 16, wherein the dimension variation amount information includes at least one of a shift amount from a dimension average value of the mask pattern and an in-plane variation of the mask pattern.

20. The method according to claim 16, further comprising deriving the allowable variation amount by using a dimension predetermined value of the on-substrate test pattern set when manufacturing the second photomask, mask pattern data on the second photomask, and an exposure condition when forming the on-substrate test pattern.
